(19) United States
(12) Patent Application Publication
(10) Pub. No.: US 2019/0391207 A1
(43) Pub. Date: Dec. 26, 2019

(54) METHOD FOR DETERMINING FAULTS IN A GENERATOR, AND GENERATOR TEST SYSTEM

(71) Applicant: Wobben Properties GmbH, Aurich (DE)

(72) Inventors: Stefan BIEHLE, Großheide (DE); Matthias JANSSEN, Rhauderfehn (DE)

(21) Appl. No.: 16/480,959

(22) PCT Filed: Jan. 30, 2018
(86) PCT No.: PCT/EP2018/052235

§ 371 Date: Jul. 25, 2019

(30) Foreign Application Priority Data
Feb. 1, 2017 (DE) 10 2017 101 944.8

(51) Int. Cl. G01R 31/34; H02K 11/20; G01R 31/02; G01R 33/02

(52) U.S. Cl. CPC G01R 31/343; H02K 11/20; G01R 33/02; G01R 31/025; G01R 31/346

(57) ABSTRACT

Thus there is provided a method of determining faults in a stator of a generator, in particular a synchronous generator of a wind turbine. The stator has a plurality of stator coils. A current source for generating a current flow through the winding of the generator is connected. A magnetic field which is generated by stator coils of the generator is detected by a means for detecting a magnetic field. A position of a fault is ascertained by identifying those stator coils which do not generate a magnetic field.

### BACKGROUND

### Technical Field

The present invention concerns a method of determining a fault on a generator and a generator test system.

### Description of the Related Art

Various electrical faults can occur in such generators of a wind turbine. FIG. 1A shows a diagrammatic view of an earth fault in a generator. The generator has various stator coils. The generator can be coupled to a rectifier by way of a terminal 1U1. The stator winding can be connected in a star point by way of a terminal 1U2.

An earth fault is an unwanted and electrically conductive connection of a phase (outer conductor or the neutral conductor/central conductor) to earth or earthed parts. An earth fault can occur due to damage to the phase, the neutral conductor or the insulation thereof. In addition an earth fault can be caused if the insulation portion of the outer or neutral conductor is bridged over by for example fouling or excess voltage. An earth fault represents a severe hazard potential because in that fault situation very high currents can occur, which can represent both a very high mechanical and also thermal loading for the defective phase or the defective neutral conductor.

FIG. 1B shows a diagrammatic view of a system fault in a generator. The generator has a plurality of stator coils. The generator can be coupled to a rectifier by way of a first terminal 1U1 and the terminal 2U1. Furthermore the generator can have a plurality of terminals 1U2, 2U2 as connections of a star point.

A system fault is an unwanted and electrically conductive connection of a phase (outer conductor) in relation to another phase of another system. Accordingly both phases may not be active in the same network, but can be live at the same time. That connection can occur due to damage to the phases or the insulation thereof. A system fault can also be caused if the insulation portion of the phase is bridged over by for example fouling or excess voltage. In the case of a system fault no current flows to earth, but only by way of the phases. A system fault represents a hazard potential because in that fault situation very high currents can occur, which can represent both a very high mechanical and also thermal loading for the defective phases.

A phase leakage fault is an unwanted and electrically conductive connection of a phase (outer conductor) or the neutral conductor (central conductor) in relation to another phase. A phase leakage fault is also referred to as a short circuit. A phase leakage fault can arise by virtue of damage to the phase or the neutral conductor of the insulation thereof. In addition thereto a phase leakage fault can be caused when the insulation portion of the phase or the neutral conductor is bridged over by for example fouling or excess voltage. In the case of a phase leakage fault no current flows to earth but only by way of the phases or the neutral conductors. The phase leakage fault represents a severe hazard potential because in that fault situation very high currents can occur, which can represent a high mechanical and thermal loading for the defective phases or the defective neutral conductor.

FIG. 1C shows a diagrammatic view of a phase leakage fault in the case of a generator. The generator can have a plurality of coils, terminals for connection to a rectifier 1U1, 1V1 and terminals for a star point 1U2, 1V2.

In relation to fault finding in the case of a synchronous generator, in particular at the stator, a fault in the stator winding has typically been detected on the basis of the control of the wind turbine. For that purpose a fault message can be generated and communicated. A member of the service team will then firstly carry out a visual check and, if the fault is not visible, he will dismantle the generator connecting cable and then open the star point connection. If the wind turbine is equipped with fault current monitoring the defective phase of the generator can then be ascertained. If the generator does not have such a fault current monitoring arrangement then the defective phase of the generator has to be ascertained by means of insulation measurement. In order further to narrow down the fault it may be necessary to isolate the defective phase by disconnection. For that purpose it may be necessary to disconnect the stator winding at a plurality of locations. After each separation a renewed insulation measurement procedure can be carried out in order to determine the defective half of the separated portion. That is repeated by the service team member until the position of the fault has been ascertained. A repair can then be carried out.

FIG. 1D shows a diagrammatic view of an earth fault on a rotor of a generator. The generator has a plurality of pole shoes as well as a positive terminal + and a negative terminal −.

In the case of an externally excited synchronous generator electrical faults can also occur in the rotor winding. In order to ascertain a fault in the rotor typically a visual check is firstly carried out by the service team. If that does not result in success it may be necessary to separate off the pole shoe groups and carry out insulation measurement of the individual groups. For that purpose the pole shoe circuits at the rotor can be separated out to isolate a fault position. After each separation a renewed insulation measurement procedure can be performed to ascertain a defective half. That is continued until the fault or the position of the fault is found. A repair can then be suitably carried out.

Troubleshooting and corresponding removal of the fault in a generator (for example a synchronous generator) of a wind turbine is thus highly time-consuming, which can result in long stoppage times for the wind turbine. In addition the repair costs caused thereby are very high. During the repair time the wind turbine cannot be operated and thus cannot generate any electric power and deliver it to the network. Consequently an operator of the wind turbine also does not receive any remuneration for the power which has not been fed into the network.

On the German patent application from which priority is claimed the German Patent and Trade Mark Office searched the following documents: DE 31 37 838 C1, DE 695 27 172 T2, US 2016/0033580 A1, WO 2010/040767 A1 and WO 2016/112915 A1.

### BRIEF SUMMARY

The present invention concerns a method of determining a fault on a generator and a generator test system. For example in relation to electric generators for wind turbines there should be a possible way of testing the mode of operation of the generator even in the installed state. In particular this involves looking for faults in installed generators of a wind turbine and in particular improving synchronous generators.

Provided is a method of fault finding in a generator of a wind turbine, in which a fault finding procedure can be carried out effectively and inexpensively.

Provided is a method of determining faults in a stator of a generator, in particular a synchronous generator of a wind turbine. The stator has a plurality of stator coils. A current source for generating a current flow through the winding of the generator is connected. A magnetic field which is generated by stator coils of the generator is detected by a means for detecting a magnetic field (that is, a magnetic field sensor). A position of a fault is ascertained by identifying those stator coils which do not generate a magnetic field.

According to an aspect of the present invention in the case of an earth fault the current source is connected both to earth and a first terminal. In the case of a system fault the current source is connected between the first terminals of the defective phases of the stator winding. In the case of a phase leakage fault the current source is connected between the first terminals.

Provided is a method of determining faults in a rotor of a generator, in particular an externally excited synchronous generator of a wind turbine. In that case the rotor has a plurality pole shoes. A DC source is connected with its positive terminal to a rotor winding of the rotor of the generator. A direct current is fed in by way of the positive terminal. The magnetic fields generated by the pole shoes are detected. The fault location is determined by comparison of the detected magnetic fields of the pole shoes, wherein the fault is present before that pole shoe at which no magnetic field is detected.

According to an aspect of the present invention, there can be provided a generator test system for determining faults in a stator of a generator or in a rotor of a generator. The test system has a current source for generating a current flow through stator coils or through pole shoes of the generator and means for detecting the presence of a magnetic field (for example a magnetic field sensor or magnetometer) of the stator coils or the pole shoes, wherein the presence of the magnetic field is viewed as an indicator for the functionality of the stator coils or the pole shoes.

According to an aspect of the invention, a current source is provided and suitably connected to the rotor or stator windings of the generator in order to provide a current flow which generates a homogeneous magnetic field around the current-carrying phase. A fault in the phase can then be detected by means of a magnetometer (teslameter). As an alternative thereto when using a DC source it is possible to employ a clip-on ammeter for detecting the fault in the rotor. If an AC source is used an alternating magnetic field occurs due to the current flow through the current-carrying phase, in which case a fault position can be determined by means of the magnetometer (teslameter).

A current source (direct current DC or alternating current AC) is provided in an earth fault situation between earth and a terminal to the rectifier. In a system fault situation a current source is connected to the defective phases. In a phase leakage fault situation in the stator a current source is connected to the terminals of the defective phases.

An electrical field can be detected at measurement points in the region of the respective windings by means of a magnetometer (teslameter).

For checking for a fault in the rotor it is possible to provide a DC source between the positive terminal or the negative terminal and the earth terminal.

According to an aspect of the present invention, there is provided in particular a method of fault finding and fault elimination in a generator of a wind turbine. Such a generator is preferably an externally excited synchronous generator having a nominal power output of at least 1 MW. In addition the generator can be of a diameter of several meters. The stator of the generator can have a plurality of stator coils (for example up to 32 or more coils). The rotor of the generator can have a plurality of pole shoes, for example up to 96 pole shoes.

According to an aspect of the present invention, it is to be possible to investigate the generator in the installed state in the wind turbine in order to find a corresponding fault.

A terminal of a secondary side would be connected after dismantling of the generator connecting line at the winding beginning of an intact adjacent phase. The other terminal of the secondary side is connected at the winding end of the same phase. By virtue of connection of the current source a current flow is produced, which in turn generates an alternating magnetic field around the current-carrying phase, which induces a voltage in the adjacent defective phase. The fault location can then be located by ascertaining the voltage components.

According to an aspect of the present invention, the means for detecting the magnetic field can be implemented in the form of a compass (for example by a smartphone with a corresponding teslameter app) or in the form of a magnetic field tester or the like. In particular the means can be in the form of a unit which is influenced by a magnetic field.

According to an aspect of the present invention, the current source can be so designed that it can also supply higher current strengths up to 200 A. That can permit easier detection of the magnetic field. For industrial safety reasons the voltage can be limited to 120V DC voltage or a voltage of 50V AC voltage.

The means for detecting a magnetic field can be in the form of a magnetometer, a teslameter, a magnetic field sensor, a magnet holder or a clip-on ammeter.

Further configurations of the invention are subject-matter of the appendant claims.

### BRIEF DESCRIPTION OF THE SEVERAL VIEWS OF THE DRAWINGS

Advantages and embodiments by way of example of the invention are described in greater detail hereinafter with reference to the drawing.

FIG. 1A shows a diagrammatic view of an earth fault in a generator,

FIG. 1B shows a diagrammatic view of a system fault in a generator,

FIG. 1C shows a diagrammatic view of a phase leakage fault in a generator,

FIG. 1D shows a diagrammatic view of an earth fault in a rotor of a generator,

FIG. 2 shows a diagrammatic view of a wind turbine according to the invention,

FIG. 3 shows a diagrammatic view of a fault finding procedure in an earth fault of a generator,

FIG. 4 shows a diagrammatic view of a fault finding procedure in a system fault of a generator,

FIG. 5 shows a diagrammatic view of a fault finding procedure in a phase leakage fault of a generator, and

FIG. 6 shows a diagrammatic view of a fault finding procedure in an earth fault of a rotor of a generator.

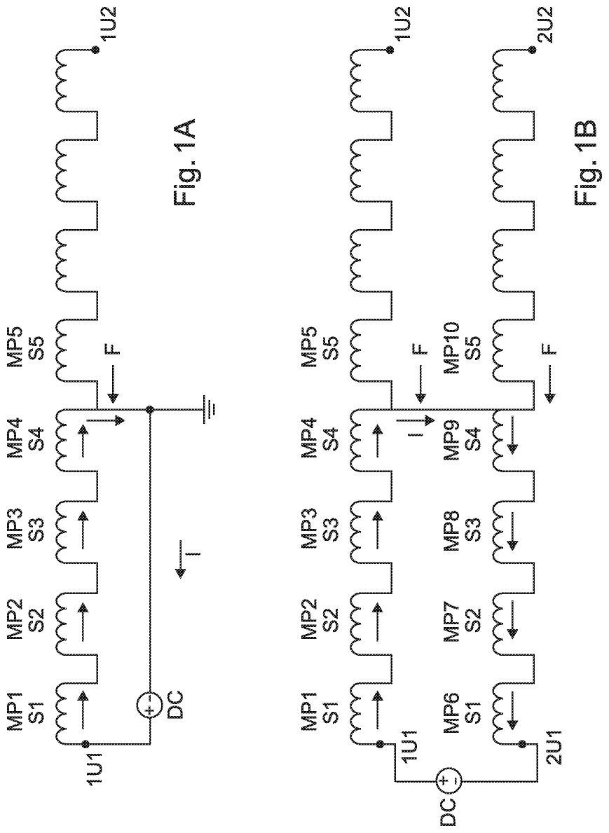

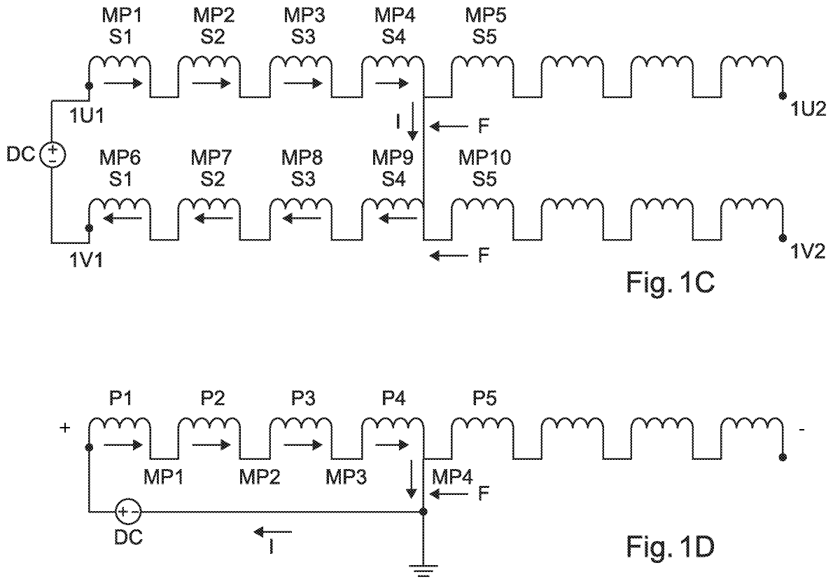

### DETAILED DESCRIPTION

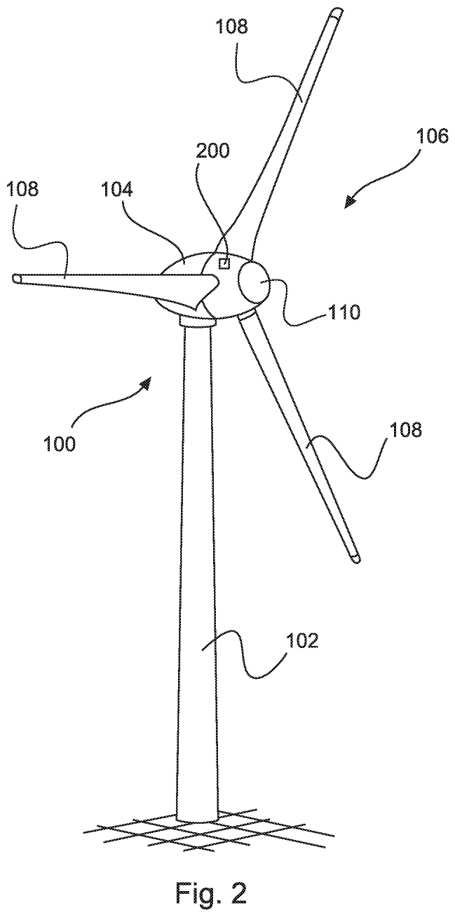

FIG. 2 shows a diagrammatic view of a wind turbine according to the invention. The wind turbine has a tower 102, a pod 104, a rotor 106 having three rotor blades 108 which are driven in rotation by the wind and can drive an electric generator 200. The rotor of the generator 200 is coupled to the aerodynamic rotor 106 of the wind turbine. The generator is preferably in the form of a synchronous generator. Optionally the generator 200 can be in the form of an externally excited synchronous generator.

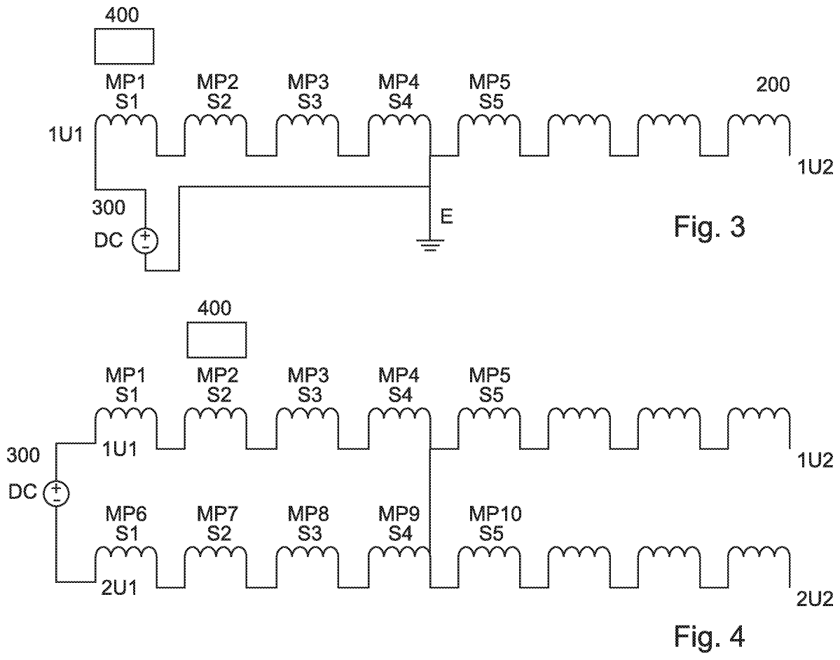

FIG. 3 shows a diagrammatic view of a fault finding procedure in relation to an earth fault of a generator. The generator 200 to be investigated, in particular the stator of the generator, has a plurality of stator coils S1-S5 so that there, that is to say at the winding head at any location between the coils, it is possible to perform a measurement at those measurement points MP1-MP5. A current source 300 is provided between earth E and the first terminal 1U1. The current source 300 can be in the form of a DC source or an AC source. By the application of the current source 300, a current flow is produced, as well as an electric field resulting therefrom in the stator winding. By means of a magnetometer (magnetic field sensor, means for detecting a magnetic field) 400 it is possible at the respective measurement points MP1-MP5 to detect a magnetic field generated by the stator coils. In the present case for example no magnetic field can be detected at the fifth measurement point MP5, that is to say at the fifth stator coil S5. It is thus clear that there is an earth fault between the fourth and fifth stator coils S4, S5. It is accordingly possible to ascertain that no current flows between the earth fault and the star point terminal 1U2.

FIG. 4 shows a diagrammatic view of a fault finding procedure in relation to a system fault of a generator. In the case of a system fault in the generator, for example in a generator of the wind turbine, a current source 300 is connected to the terminals 1U1, 2U1 of the defective phases. Due to the current source 300 which can be in the form of a DC or AC current source an electric current flows through the stator coils and generates a magnetic field. Then by means of the magnetometer 400, it is possible at the respective measurement points MP1-MP4, MP6-MP9, to detect a magnetic field generated by the respective stator coils. No magnetic field can be detected at the measurement points MP5 and MP10. It is thus clear that the system fault must be between the measurement points MP4 and MP9 so that no current can flow between the system fault and the star terminals 1U2, 2U2.

For example a current flow of 50 A can be generated by means of the current source so that the magnetometer 400 can measure measurement values in the region of for example 2mT (millitesla) if the magnetometer 400 is held directly at the conductor of the stator coils. In that case for example only measurement values in the region of <50 mT can be measured at the measurement points MP5 and MP10. Thus the system fault can be clearly determined, in that the absence of a magnetic field can be reliably determined at the measurement points MP5 and MP10.

As an alternative to the magnetometer it is possible to use a magnet holder in order to establish whether there is a magnetic field in the respective stator coils. A magnet holder is typically provided to suspend a measuring device on a metallic item. That magnet holder can be guided along the winding of the phases in the case of a current flow of for example 50 A, generated by the current source 300. At the measurement points MP1-MP4, MP6-MP9 in which there is no fault, the magnet holder is attracted or repelled according to the polarity of the stator coils. A magnetic holder is neither attracted nor repelled at the measurement points MP5, MP10, that is to say where the fault is present.

According to an aspect of the present invention therefore a means 400 is used for detecting a magnetic field in order to establish whether the respective stator currents do or do not generate a magnetic field. If they do not generate a magnetic field when the current source is applied then no current flows through those stator coils so that the fault must be present in the region.

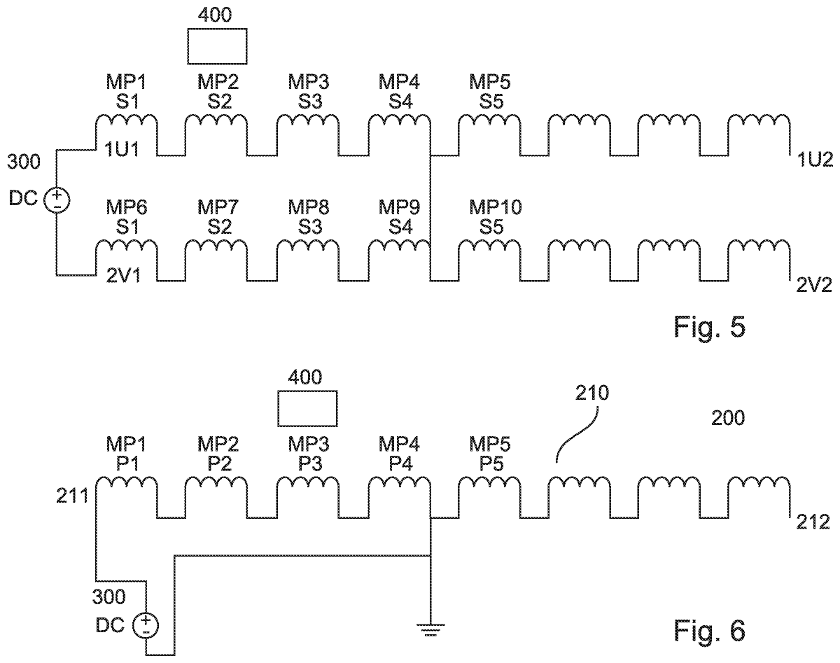

FIG. 5 shows a diagrammatic view of a fault finding procedure in relation to a phase leakage fault of a generator. The generator has a plurality of stator coils S1-S5. A current source 300 (which can be in the form of a DC or AC current source) is connected to the terminals 1U1, 2V1 of the winding and then delivers a current, for example of 50 A. In the example in FIG. 5 there is a phase leakage fault in the stator winding of the generator 200. Using a magnetometer 400 it is possible at the measurement points MP1-MP10 to test whether the respective stator coils generate a magnetic field. While a magnetic field is detected at the measurement points MP1-MP4 and MP6-MP9 by means of the magnetometer 400 no magnetic field is detected at the measurement points MP5, MP10 so that it is therefore clear that the system fault is present between the fourth measurement point MP4 and the ninth measurement point MP9. As already described in relation to FIG. 4 the means 400 for detecting the magnetic field can also be in the form of a magnet holder.

FIG. 6 shows a diagrammatic view of a fault finding procedure in relation to an earth fault of a rotor of a generator. The rotor 210 of the generator 200 can have a plurality of pole shoes P1-P5. In addition the rotor can have a positive terminal 211 and a negative terminal 212. To detect the fault in the rotor of the generator 200 a DC voltage source 300 is provided between earth and the positive terminal 211.

The magnetic field at the measurement points MP1-MP5 is detected by the means 400 for detecting the magnetic field which can be in the form of a magnetometer. While a respective magnetic field can be detected at the measurement points MP1-MP4 no magnetic field is detected at the measurement point MP5. It is thus clear that there is an earth fault between the measurement points MP4 and MP5 so that no current can flow between the earth fault and the negative terminal 212.

If for example the current source permits a current flow of 10 A then measurement values in the region of a millitesla can be ascertained by means of the magnetometer 400. Measurement values in the region of <50 mT can be ascertained at the measurement point MP5, that is to say where there is no magnetic field.

As already described hereinbefore in relation to FIG. 4 a magnet holder can also be used as an alternative to the magnetometer.

As a further configuration of the means 400 for detecting the magnetic field it is possible to use a clip-on ammeter. A clip-on ammeter can be placed around the connecting lines of the pole shoes at the measurement points MP1-MP4 in order to detect a current. As no current is detected at the measurement point MP5 it is thus possible to establish that the earth fault is between the fourth and fifth measurement points MP4-MP5.

The means 400 for detecting the magnetic field can be in the form of a magnetometer, a clip-on ammeter or a magnet holder. The mode of operation of the means 400 for detecting the magnetic field is secondary in this respect as long as the means is suitable for detecting a magnetic field.

If it is established for example by insulation measurement that there is an earth fault in the stator then the connecting line of the negative pole of the generator test device can be connected with a crocodile clip to an unpainted part of the generator. The connecting line of the negative pole of the generator test device can be connected with a crocodile clip at the terminal board to the defective phase of the stator winding. The generator test device is activated, that is to say the current source is activated, and a current flow is established. The magnetic field generated by the respective stator coils is detected by means of the magnetometer.

According to an aspect of the present invention, means are provided for detecting a magnetic field or a field of a magnet. Those means serve to determine the presence or the absence of a magnetic field generated by a stator coil or by a pole shoe of the generator. On the basis of the presence or absence of a magnetic field it is possible to draw conclusions about the function or functionality of the stator coils or the pole shoes of the rotor. In other words, a fault in the stator coils or the pole shoes of the rotor can be ascertained on the basis of the measurement results of the magnetic field.

1. A method of determining one or more faults in a stator of a generator, wherein the stator has a plurality of stator coils of a stator winding, the method comprising:
for generating a current flow through the stator winding;
detecting whether a magnetic field is generated by the plurality of stator coils; and
ascertaining a position of the one or more faults by identifying one or more stator coils of the plurality of stator coils that do not generate a magnetic field.

2. The method according to claim 1, wherein generating the current flow through the stator winding comprises connecting a current source to the stator winding, wherein:
in the case of an earth fault, connecting the current source both to earth and a first terminal;
in the case of a system fault, connecting the current source between the first terminal and a second terminal of defective phases of the stator winding; and
in the case of a phase leakage fault, connecting the current source between the first terminal and a second terminal.

3. A method of determining one or more faults in a rotor of a generator, wherein the rotor has a plurality of pole shoes of a rotor winding, the method comprising:
connecting a direct current source to a positive terminal of the rotor winding of rotor of the generator;
feeding a direct current into the positive terminal;
detecting magnetic fields generated by the plurality of pole shoes;
comparing the plurality of detected magnetic fields; and
determining the one or more fault locations by the comparison of the detected magnetic fields of the plurality of pole shoes.

4. The method according to claim 3 wherein detecting a detecting the magnetic field includes using a magnetometer or a clip-on ammeter.

5. A generator test system for determining faults in a stator or a rotor of a generator of a wind turbine comprising:
a current source for generating a current flow through a plurality of stator coils of the stator of the generator or through a plurality of pole shoes of the rotor of the generator; and
a magnetic field sensor coupled to the plurality of stator coils or the plurality of pole shoes and configured to measure the magnetic field of the plurality of stator coils or the plurality of pole shoes.

6. A method of using a generator test system for determining faults in a stator or a rotor of a generator of a wind turbine, the method comprising:
using a current source generating a current flow through a plurality of stator coils of the stator of the generator or through a plurality of pole shoes of the rotor of the generator; and
using a magnetic field sensor to detect a magnetic field of the plurality of stator coils or the plurality of pole shoes,
wherein a position of a fault is determined by identifying one or more stator coils of the plurality of stator coils or one or more rotor coils of the plurality of rotor coils that do not generate a magnetic field.

7. The method according to claim 1, wherein the generator is a synchronous generator of a wind turbine.

8. The method according to claim 3, wherein the fault is located at the pole shoe at which a magnetic field is not detected.

9. The method according to claim 1, wherein generating the current flow through the stator winding comprises connecting a current source to the stator winding.

10. The generator test system according to claim 5, wherein the generator is a synchronous generator of a wind turbine.

11. The generator test system according to claim 5, wherein the generator is an externally excited synchronous generator of a wind turbine.
